(19) United States
(12) Patent Application Publication
(10) Pub. No.: US 2013/0169127 A1
(43) Pub. Date: Jul. 4, 2013

(54) OUTER CASING FOR ELECTRIC DEVICE

(71) Applicant: PANASONIC CORPORATION, Osaka (JP)

(72) Inventors: Takashi NAGASHIMA, Kyoto (JP); Suguru NAKAO, Hyogo (JP)

(73) Assignee: PANASONIC CORPORATION, Osaka (JP)

(21) Appl. No.: 13/780,699

(22) Filed: Feb. 28, 2013

Related U.S. Application Data
(63) Continuation of application No. PCT/JP2012/002865, filed on Apr. 26, 2012.

(30) Foreign Application Priority Data
Sep. 26, 2011 (JP) 2011-208585

(51) Int. Cl. H05K 5/02

(52) U.S. Cl. CPC H05K 5/02
USPC 312/223.1

(57) ABSTRACT

A molded article having a flexural strength of 40 MPa or more and including a flame-retarded resin composition including a resin component containing 50% by weight or more of poly(lactic acid) and/or a lactic acid copolymer, and silica-magnesia catalyst particles as a flame retardance-imparting component which imparts flame retardancy, is used as an outer casing of an electric device, thereby providing an electric device which is earth-conscious and is less likely to generate a chatter noise, and also has an appearance of a high specular glossiness.

### CROSS REFERENCE TO RELATED APPLICATIONS

This is a continuation application of PCT Application No. PCT/JP2012/002865, filed on Apr. 26, 2012, designating the United States of America, which claims the priority of Japanese Patent Application No. 2011-208585, filed on Sep. 26, 2011, the disclosure of which, including the specifications, drawings, and claims, are incorporated herein by reference in their entireties.

### BACKGROUND OF THE INVENTION

### Field of the Invention

The present disclosure relates to an outer casing for an electric device, for example, electric appliances such as thin, lightweight and flat display devices, and common electronic components such as resistors and speakers.

As flat display devices, liquid crystal displays, organic EL displays, plasma displays and the like are produced in a commercial basis. Since liquid crystal displays and plasma displays in particular are thin and capable of displaying on large screens, they have become widely and commonly used as displays in public facilities and the like, in addition to ordinary households.

In cases of such display devices, resin molded articles are employed as their outer casings so as to meet design requests and to make them lighter. With these display devices becoming widely used, there is being posed, as a problem, disposal treatment of resin molded articles when spent devices are disposed of.

Recently, attention has been directed to resins (or plastics) which decompose by bacterial action when they are buried in the ground. These resins, which are called biodegradable resins (or plastics), have characteristics of being degraded into water (H₂O) and carbon dioxide (CO₂) in the presence of aerobic bacteria. Biodegradable resins are in practical use in the field of agriculture and also in practical use, for example, as packaging materials for disposable articles and as materials of compostable garbage bags.

Articles using biodegradable resins, for example, when used in the field of agriculture, may be advantageous also to users because spent plastics do not need to be collected. Further, in recent days, plant-derived resins are also receiving attention in the fields of electronic devices and automobiles. Plant-derived resins are obtained by polymerization or co-polymerization of monomers obtained from plant materials. Plant-derived resins receive attention as earth-conscious resins, for example, for reasons that they can be produced without relying on oil resources, that plants used as raw materials absorb carbon dioxide and grow, and that their combustion calories are generally low and the amount of generated CO₂ is small even when their disposal is performed by an incineration treatment. Plant-derived resins are generally biodegradable, but do not necessarily need to be biodegradable when considered only from a viewpoint of preventing the depletion of oil resources. From this, resins which contribute to environmental protection will include, in addition to biodegradable resins, plant-derived resins which are not biodegradable. Hereinafter, these resins are referred to collectively as “environmental resins”.

At present, resins which are in use as environmental resins are divided into three main classes: those based on poly(lactic acid) (hereinafter, sometimes referred to as “PLA”), on PBS (polybutylene succinate (a copolymeric resin of 1,4-butanediol and succinic acid)), and on PET (modified polyethylene terephthalate).

Among these resins, PLAs can be produced by chemical synthesis in which sugars generated by plants such as corns or sweet potatoes are used as raw materials, and have a possibility of industrial production. Plastics containing such plant-derived resins are referred to as bioplastics. Particular attention is paid to PLAs because mass production of PLAs has been begun using corns as raw material, and thus there is a desire to develop a technology by which PLAs can be applied not only to applications requiring biodegradation properties, but also to a wide variety of applications.

As methods for improving characteristics of such environmental resins, there were proposed methods by which other components were incorporated into them. For example, JP-A 2002-173583 proposes that synthetic mica is incorporated into PLA in the order of 0.5% to 20% by weight, in order to improve the heat resistance of PLA.

In addition, there was reported the possibility of applying of PLAs to personal-computer outer casings by incorporating kenaf fibers into PLAs (Serizawa et al., “Development of Kenaf-Fiber-Reinforced Poly(lactic acids),” Proceedings of the 14th Annual Meeting of the Japan Society of Polymer Processing, pp. 161-162, 2003). Specifically, it was reported that after molding PLA resins having kenaf fibers incorporated therein, the addition of an annealing step resulted in an improved heat resistance of the PLA resins, thereby leading to a higher possibility of applying PLAs to personal-computer outer casings.

### SUMMARY OF THE INVENTION

The resin compositions described in the above-mentioned documents, JP-A 2002-173583 and Serizawa et al., “Development of Kenaf-Fiber-Reinforced Poly(lactic acids),” Proceedings of the 14th Annual Meeting of the Japan Society of Polymer Processing, pp. 161-162, 2003, leave room for further improvement in making up outer casings for electric devices. Specifically, the outer casings which are produced by molding the resin compositions described in these references leave room for further improvement, in terms of the generation of a “chatter noise” and/or the occurrence of “sinks” on the molded surface. For example, if an outer casing contains or is placed near a speaker, the sound waves from the speaker may cause vibration of the outer casing. An unusual noise due to the vibration is called a “chatter noise”. An outer casing, which generates a “chatter noise”, cannot be used as a commercial product.

A “sink” refers to a dimple on the surface of an outer casing which results from the shrinkage of the resin composition. When “ribs” have been placed for reinforcement on the reverse-side surface of an outer casing (the molded surface which is not visible during the use of the product), a “sink” is likely to be generated at the site on the outside surface which site corresponds to the position at which the “rib” has been placed. PLAs in particular are prone to shrinkage, in comparison to other resins, and thus are likely to cause a “sink” problem to a remarkable degree. An outer having any “sinks” caused thereon also cannot be used as a commercial product for the reason of appearance.

In addition, when a molded article is employed as an outer casing, the molded surface of the molded article may be used as a design surface to allow desired effects of the design to be exerted by the molded surface itself (i.e. without its painting or the like). Specifically, an example of such design surfaces which are required includes a glossy surface like the surface of a mirror (for example, a black glossy surface called “piano black”). However, there have not been reported examples in which molded articles having such a glossy surface are made up of PLA.

Further, the resin compositions described in the above-mentioned JP-A 2002-173583 and Serizawa et al., “Development of Kenaf-Fiber-Reinforced Poly(lactic acids),” Proceedings of the 14th Annual Meeting of the Japan Society of Polymer Processing, pp. 161-162, 2003 are those proposed for the purpose of improving heat resistance, and none of these documents mentions imparting of flame retardancy to the resin compositions which is absolutely necessary for applying them to outer casings of electric devices represented by home appliances. Actually, the resin compositions described in the above-mentioned documents do not have flame retardancy. Thus, none of the PLA compositions which have been proposed in the past can be applied to outer casings of electric devices such as television sets having high-voltage parts in their inside. In addition, recent electric devices emphasize safety and there is a tendency to employ flame-retarded resins even in cases of electric devices having no high-voltage elements in their inside. Therefore, even though environmental resins have characteristics satisfactory in stiffness, impact strength, heat resistance and the like, their usefulness will be extremely low unless they have flame retardancy.

The present disclosure provides an outer casing for an electric device which is made up of an environmental resin, such as poly(lactic acid) (PLA) and/or a lactic acid copolymer and has satisfactory properties as an outer casing for an electric device.

The present disclosure provides an outer casing for an electric device, including a molded article which is made up of a flame-retarded resin composition, the resin composition including a resin component containing 50% by weight or more of poly(lactic acid) and/or a lactic acid copolymer, and silica-magnesia catalyst particles as a flame retardance-imparting component which imparts flame retardancy,

wherein the resin composition has a flexural strength of 40 MPa or more, and

the molded article has a glossy surface having a 20 degree specular glossiness (Gₛ(20°)) of 60 or more, measured according to JIS Z 8741.

According to the present disclosure, it is possible to provide an electric device including an outer casing which is made up of a resin composition, the resin composition including an earth-conscious and preferably biodegradable environmental resin as the main resin component and having flame retardancy imparted thereto, the electric device being less likely to generate a chatter noise, and having the appearance of a high specular glossiness.

### BRIEF DESCRIPTION OF THE DRAWINGS

FIG. 1 is a front elevation view showing the appearance of a liquid crystal display device as an example of electric devices according to an embodiment.

FIG. 2 is a perspective view showing a state where a stand is removed in the liquid crystal display device shown in FIG. 1.

FIG. 3 is a block diagram showing circuit blocks in the whole configuration of the liquid crystal display device shown in FIG. 1.

FIG. 4 is a plane view showing an example of layout of the circuit blocks of the liquid crystal display device shown in FIG. 1 with the back cabinet being removed to explain the example of layout.

FIG. 5 is a plane view taken from the side of the reverse surface of a design surface in an outer casing for an electric device according to an embodiment.

FIG. 6 is a cross-sectional view showing the state of a sink which has been caused on a design surface in an outer casing for an electric device according to an embodiment.

### DETAILED DESCRIPTION OF THE INVENTION

An embodiment of an outer casing for an electric device according to the present disclosure will be described below with reference to the accompanying drawings.

It should be noted that the present inventor provides the attached drawings and the following description such that those skilled in the art understand the present disclosure sufficiently, and these are not intended to limit the subject matters described in the claims.

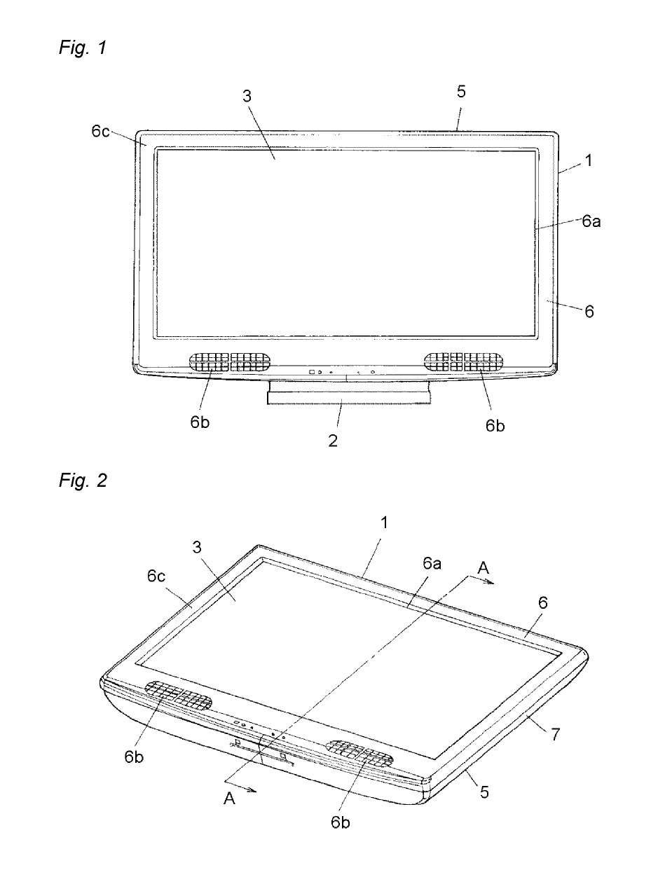

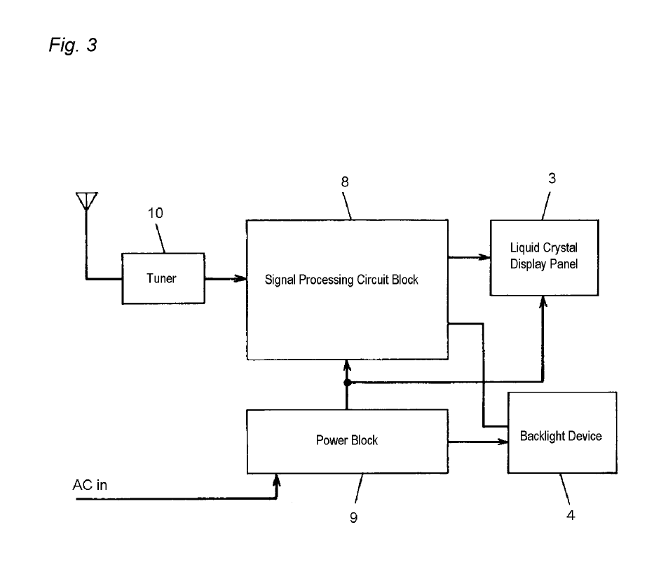

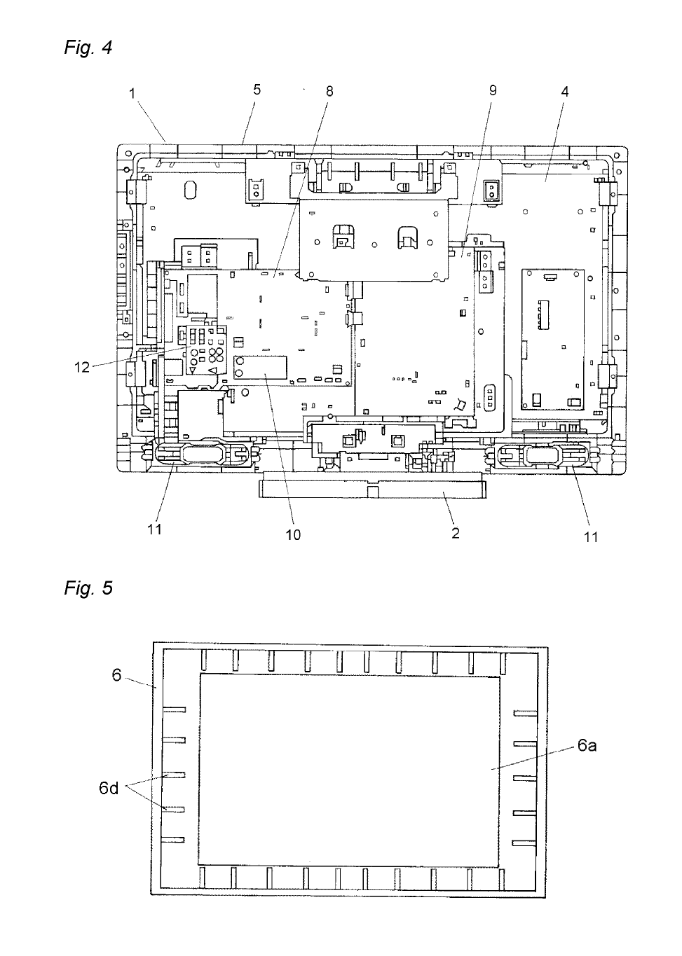

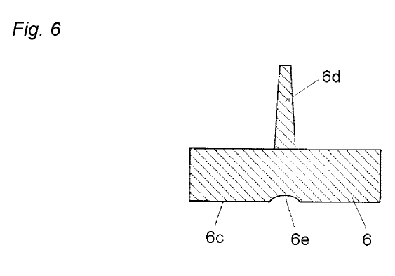

FIGS. 1 and 2 are a front elevation view and a perspective view showing the appearance of a liquid crystal display device as an example of electric devices according to an embodiment, respectively. FIG. 3 is a block diagram showing circuit blocks in the whole configuration of the liquid crystal display device, and FIG. 4 is a plane view showing an example of layout of the circuit blocks of the liquid crystal display device with the back cabinet being removed to explain the example of layout.

As shown in FIGS. 1 and 2, a liquid crystal display device has a display device body 1 and a stand 2 for retaining the display device body 1 in a state allowing it to stand up. The display device body 1 is made up by placing a display module consisting of a liquid crystal display panel 3, which is a flat display panel, and a backlight device (not shown in FIGS. 1 and 2) into an outer casing 5 of a resin molded article or the like.

The outer casing 5 is composed of a front cabinet 6 with an opening 6a provided therein so as to conform to the image display area of the liquid crystal display panel 3; and a back cabinet 7 to be combined with the front cabinet 6. 6b refers to a speaker grille for releasing sounds emanated from a speaker to the outside. In the front cabinet 6 of the outer casing 5, the frame portion surrounding the opening 6a has a glossy design surface 6c, which provides the outer casing with external beauty.

As shown in FIGS. 3 and 4, a rough configuration of the whole liquid crystal display device is one which has a signal processing circuit block 8 including a driving circuit for displaying images on a liquid crystal display panel 3 and a lighting control circuit for controlling lighting of a backlight device 4; a power block 9 for supplying source voltages to the liquid crystal display panel 3, the backlight device 4, and the signal processing circuit block 8; a tuner 10 for receiving television broadcasting to provide the received signal to the signal processing circuit block 8; and a speaker 11 for outputting sound. The signal processing circuit block 8 and the power block 9 are both made by mounting the parts composing the circuit on a circuit board. The circuit board on which the signal processing circuit block 8, the power block 9, the tuner 10 and the like have been mounted is fixed such that it is positioned in the space between the back side of the backlight device 4 and the back cabinet 7.

In FIG. 3, a speaker is omitted. In FIG. 4, reference numeral 12 refers to external signal input terminals for inputting image signals from external devices, such as DVD players, to the liquid crystal display device and is mounted in the signal processing circuit block 8.

The present disclosure is directed to an outer casing for a display device such as the liquid crystal display device as described above, or other electric device, which is obtained by molding a flame-retarded resin composition including a resin component containing 50% by weight or more of poly(lactic acid) and/or a lactic acid copolymer, and silica-magnesia catalyst particles as a flame retardance-imparting component which imparts flame retardancy.

Thus, the flame retardancy is imparted to the resin composition by mixing particles of a silica-magnesia catalyst, which is one used in purification, cracking, synthesis, or reforming of hydrocarbons, into poly(lactic acid) and/or a lactic acid copolymer.

As used herein, “flame retardance” or “flame retardancy” refers to properties by which the combustion does not continue or no afterglow is brought about when the source of ignition is removed. As used herein, “flame retardance-imparting component” which imparts flame retardancy refers to a component which makes a resin flame-retardant by its addition thereto. Silica-magnesia catalyst particles as the flame retardance-imparting component used in the present disclosure are a catalyst which is used in purification, cracking, synthesis, and/or reforming of hydrocarbons and which is in the form of compounds that do not contain halogens at all or are difficult to generate dioxins. In the present disclosure, a catalyst as the flame retardance-imparting component exerts effects characteristic of the catalyst during the combustion reactions of the resin component in the process where the resin component actually burns, when the catalyst and the resin component are kneaded in advance, thereby to disperse the catalyst into the resin component. These catalytic effects significantly contribute to making the resin flame-retardant.

When the silica-magnesia catalyst particles are subjected to high temperatures (for example, in the order of 500° C. or higher) during combustion, the silica-magnesia catalyst particles cut macromolecules, which are of the resin component, from their ends, thereby decomposing them into lower molecular-weight molecules. If the molecular weights of molecules after the decomposition are small, then the total molecular weight of the flammable gases belching by thermal decomposition is decreased, whereby making the resin component flame-retardant would be achieved. In general, the combustion of a resin continues by the combustion cycle that the energy which is generated when molecules produced by thermal decomposition of the resin during the combustion are burned is provided to the resin as radiation heat, which causes further thermal decomposition of the resin and combustion of molecules produced by the decomposition. If the molecular weight of molecules produced by decomposition of a resin is larger, and thus more gases as fuel are supplied, then the energy of combustion will become higher. In addition, as the energy of combustion becomes great, the radiation heat in the combustion field is increased and the combustion of the resin lasts for a longer period of time. Therefore, when a resin is cut at the same number of times, decomposing of the resin into molecules with smaller molecular weights is preferable in that the energy of combustion is decreased and the thermal decomposition of the resin is suppressed. Silica-magnesia catalyst particles would exert catalytic effects so as to decompose a resin into molecules with smaller molecular weights during the combustion of the resin. This flame-proofing mechanism is different from those of halogen-based and phosphorus-based flame retardants. For example, in the case of halogen-based flame retardants represented by bromine-based flame retardants, halogen-containing gas components generated by thermal decomposition capture radicals released from a resin in the vapor phase, thereby suppressing combustion reactions. It is said that the phosphorous-based flame retardants facilitate the formation of a carbonized (char) layer during the combustions, which blocks oxygen and radiation heat, thereby suppressing the combustion.

The flame-retarded resin composition which composes an outer casing for an electric device according to the present disclosure will be described in more detail below.

First, the resin component will be described.

The flame-retarded resin composition which composes an outer casing according to the present disclosure contains poly(lactic acid) (PLA) and/or a lactic acid copolymer as the resin component. PLA and a lactic acid copolymer are a resin which is obtained by using lactic acid as raw material and polymerizing it or co-polymerizing it with other monomer(s). Lactic acid can be obtained, for example, by fermentation of starch or sugars which are obtained from corns, sweet potatoes, or the like. Therefore, PLAs and lactic acid copolymers can be supplied as plant-derived resin. Many of PLAs and lactic acid copolymers have biodegradation properties. Therefore, PLAs and lactic acid copolymers are environmental resins.

PLAs and lactic acid copolymers, particularly PLAs, have superior transparency and stiffness, and thus molded articles composed of these can be used for various applications. On the other hand, PLAs and lactic acid copolymers have disadvantages of exhibiting a decreased resistance to heat and impact and a slightly decreased injection moldability. For these reasons, PLAs and lactic acid copolymers are preferably used in mixture with other resin(s) and/or modifier(s), particularly when they are injection molded. For example, since PBSs have superior heat resistance and are biodegradable per se, they are suitable for mixing into PLAs and lactic acid copolymers. Alternatively, PLAs and lactic acid copolymers may be modified using agents which are commercially available as poly(lactic acid) modifiers. Alternatively, an impact absorber, which modifies impact resistance properties, may be used.

Poly(lactic acid) may be one known in the art. For example, poly(lactic acids) may include a poly(L-lactic acid) consisting of the L-lactic acid unit; a poly(D-lactic acid) consisting of the D-lactic acid unit; a mixture including a poly(lactic acid) stereo-complex formed by mixing a poly(L-lactic acid) and a poly(D-lactic acid); or a poly(lactic acid) block copolymer obtained by solid polymerization of this mixture.

The lactic acid copolymer is a copolymer which is obtained, for example, by co-polymerizing L-lactide and/or D-lactide made from L-lactic acid and/or D-lactic acid, with an oxyacid, lactone, dicarboxylic acid, or polyhydric alcohol co-polymerizable therewith (for example, caprolactone or glycolic acid).

An outer casing according to the present disclosure contains PLA and/or a lactic acid copolymer as the resin component, wherein PLA and/or the lactic acid copolymer accounts for 50% by weight or more of the total weight of the resin component as the main ingredient. An outer casing wherein PLA and/or a lactic acid copolymer constitutes 50% by weight or more of the whole resin component is capable of its easy disposal. PLA and a lactic acid copolymer are a polymer of which flame retardancy tends to be improved by addition of silica-magnesia catalyst particles, in comparison with other polymers. Therefore, the flame retardance-imparting effect of the silica-magnesia catalyst particles can be favorably given when 50% by weight or more of the whole resin component is constituted by PLA and/or a lactic acid copolymer, resulting in reduction in the proportion of the added flame retardance-imparting component. PLA and/or a lactic acid copolymer accounts for preferably 60% by weight, more preferably 70% by weight or more, further more preferably 80% by weight or more, particularly preferably 85% by weight or more, most preferably 90% by weight or more of the resin component, and optionally 100% by weight (that is, only PLA and/or a lactic acid copolymer may be contained as the resin component).

In an outer casing, PLA and/or a lactic acid copolymer accounts for preferably 70% by weight or more, 80% by weight or more, or 85% by weight or more, or most preferably 90% by weight or more, of the flame-retarded resin composition. When PLA and/or a lactic acid copolymer accounts for 70% by weight or more of a flame-retarded resin composition, the resin composition can be disposed of with ease. Other ingredients than PLA and/or the lactic acid copolymer in the flame-retarded resin composition are other resin ingredient(s), a flame retardance-imparting component as described below, an optionally added additive(s) and the like.

In the outer casing, the resin component containing PLA and/or a lactic acid copolymer as the main ingredient may include other resin(s). Specifically, in the outer casing, the resin component of which the main ingredient is poly(lactic acid) and/or the lactic acid copolymer may include one or more resins selected from:
a thermoplastic resin, such as polyethylene, polypropylene, polystyrene, an ethylene vinyl acetate copolymer, poly(vinyl chloride), acrylonitrile-styrene (AS), an acrylonitrile/butadiene/styrene (ABS) copolymer and a mixture, poly(ethylene terephthalate) (PET), and poly(butylene terephthalate) (PBT);
a thermoplastic elastomer, such as a butadiene rubber (BR), an isoprene rubber (IR), a styrene/butadiene copolymer (SBR), a hydrogenated styrene/butadiene copolymer (HSBR), and a styrene/isoprene copolymer (SIR);
a thermoplastic engineering resin, such as polyamide (PA), polycarbonate (PC), and polyphenylene ether (PPE);
a super-engineering resin, such as polyarylate (PAR) and polyether ether ketone (PEEK); and
a thermosetting resin, such as an epoxy resin (EP), a vinyl ester resin (VE), polyimide (PI), and polyurethane (PU). The thermoplastic elastomers can serve as an impact absorber for PLA and/or the lactic acid copolymer.

Silica-magnesia (SiO₂/MgO) catalyst particles which are a flame retardance-imparting component which imparts flame retardancy will be descried below.

The silica-magnesia catalyst particles are those of a solid acid catalyst, which is prepared, for example, by hydrothermal synthesis, and is a double oxide of silicon oxide (silica) and magnesium oxide (magnesia) or a catalyst which is formed by binding both silicon oxide (silica) and magnesium oxide (magnesia). The silica-magnesia catalyst particles function as a catalyst which decomposes hydrocarbons at the time of burning of resin composition, for example, under elevated temperatures of about 500° C. or higher, as described above. On the other hand, metal oxides or mineral materials containing metal oxides (for example, talc) which are used as a filler, do not exhibit any catalytic effects even under such elevated temperatures. Therefore, the silica-magnesia catalyst particles are distinguished from such metal oxides or mineral materials.

In the outer casing, it is preferable that the silica-magnesia catalyst particles in a state having no crystal water form a mixture with the resin component. In some cases, the silica-magnesia catalyst particles having crystal water are able to impart little or no flame retardancy to the resin component. When a composition or compound (including a double oxide) containing silica and magnesia contains crystal water, its chemical formula may be represented by that having a hydroxyl group. It is preferable, from a viewpoint of imparting satisfactory flame retardancy, that the silica-magnesia catalyst particles which are contained in the outer casing according to the present disclosure are those which do not have such a hydroxyl group(s). Therefore, the silica-magnesia catalyst particles which are contained in the outer casing according to the present disclosure are preferably those which do not have hydrogen atoms composing crystal water or a hydroxyl group in the molecule.

In the present disclosure, it is preferable to use silica-magnesia catalyst particles having a percent MgO of 10% to 50% by weight. If the percent MgO of a catalyst is less than 10% by weight, the particles do not exhibit sufficient catalytic effects, that is, the particles have a weak action of decomposition of the resin, resulting in a tendency to reduce the effect of imparting flame retardancy. On the other hand, if the percent MgO of a catalyst is 50% by weight or more, the particles may exhibit too strong catalytic effects, thereby decomposing the resin into higher molecular-weight molecules, resulting in the increase in the amount of combustion heat and the decrease in flame-retarded effects.

The content of the silica-magnesia catalyst particles is determined, depending on the particle sizes of the silica-magnesia catalyst particles, the degree of flame retardancy to be required in the resin composition, and the amount of changes in the physical properties of the resin composition due to the silica-magnesia catalyst particles. Specifically, for example, it is preferable that silica-magnesia catalyst particles account for about 0.5% to about 40% by weight of the resin composition. If the content of the silica-magnesia catalyst particles is less than 0.5% by weight, it is difficult to achieve a significant effect of improvement in flame retardancy. On the other hand, if the content of the silica-magnesia catalyst particles is larger than 40% by weight, undesirable effects due to mixing of the silica-magnesia catalyst particles, such as poor moldability resulting from decreased flowability, may be significant.

In the present disclosure, it is preferable to use silica-magnesia catalyst particles having an average particle diameter of 10 μm or less. The average particle diameter is a median diameter D50, which is determined from particle sizes measured by a laser diffraction/scattering method. When the average particle diameter of silica-magnesia catalyst particles is 10 μm or less, an outer casing having satisfactory flame retardancy can be obtained even though the content of the particles is 9.0% by weight or less. As the average particle diameter of silica-magnesia catalyst particles becomes decreased, an outer casing having higher flame retardancy can be obtained at the same content of the particles. Therefore, the silica-magnesia catalyst particles having a smaller average particle diameter make it possible to obtain the outer casing having desired flame retardancy (for example, grade V0 of the UL 94 Standard), even though the content of the silica-magnesia catalyst particles is decreased.

The silica-magnesia catalyst particles having an average particle diameter of 10 μm or less, for example, 1 μm or more and 10 μm or less, are obtained by pulverizing the silica-magnesia catalyst particles which have larger particle sizes. Pulverizing may be carried out, for example, by using a jet mill.

Preferable content of the silica-magnesia catalyst particles also varies according to their average particle diameter. For example, when the average particle diameter of the silica-magnesia catalyst particles is 4 μm or more and 8 μm or less, particularly in the order of 5 μm, the flame-retarded resin composition in which a content of the silica-magnesia catalyst particles is 0.7% by weight or more and 9.0% by weight or less will exhibit a high flame retardancy (grade V0 of the UL 94 Standard). Also, when the average particle diameter of the silica-magnesia catalyst particles is 2 μm or more and less than 4 μm, particularly in the order of 3 μm, the flame-retarded resin composition in which the content of the silica-magnesia catalyst particles is 0.5% by weight or more and 9.0% by weight or less will exhibit a high flame retardancy (grade V0 of the UL 94 Standard). When the average particle diameter of the silica-magnesia catalyst particles is 8 μm or more and 15 μm or less, particularly in the order of 10 μm, the flame-retarded resin composition in which the content of the silica-magnesia catalyst particles is 1.0% by weight or more and 9.0% by weight or less will exhibit a high flame retardancy (grade V0 of the UL 94 Standard).

The flame-retarded resin composition composing the outer casing according to the present disclosure may include other component(s) than the above-described resin component and flame retardance-imparting component. As other component(s) are included additives commonly added to resins. Additives are, for example, nucleating agents such as calcium lactate and benzoates; hydrolysis inhibitors such as carbodiimide compounds; antioxidants such as 2,6-di-t-butyl-4-methylphenol and butylated hydroxyanisole; releasing agents such as glycerin mono-aliphatic acid esters, sorbitan aliphatic acid esters, and polyglycerin aliphatic acid esters; colorings such as carbon black, ketjen black, titanium oxide, and lapis lazuli; impact absorbers such as butylene rubbers; anti-fogging agents such as glycerin aliphatic acid esters and monostearyl citrate.

A flame-retarded resin composition composing an outer casing according to the present disclosure preferably does not include a filler. If the flame-retarded resin composition includes a filler, then a molded article from such a flame-retarded resin composition may be not shiny on the molded surface. Herein, a filler is a fiber- or plate-like material of glass or inorganic substance and refers to an additive which improves the flexural strength of a resin composition. The silica-magnesia catalyst particles are distinguished from a filler, in that even when silica-magnesia catalyst particles are added to a resin composition, there is no improvement in the flexural strength of the resin composition.

The flame-retarded resin composition can be produced by kneading a resin component, a flame retardance-imparting component, and an additive(s) which is/are optionally added. As an example, the flame-retarded resin composition can be produced by methods in which silica-magnesia catalyst particles are added in a kneading step wherein the resin component having poly(lactic acid) and/or the lactic acid copolymer as the main ingredient is molten and kneaded. According to this production method, another step for incorporating the flame retardance-imparting component does not take place, and thus the flame-retarded resin composition can be obtained without increasing the production cost so much.

Preferably, the silica-magnesia catalyst particles are subjected to heat treatment prior to being kneaded with the resin component. This is due to the fact that silica-magnesia catalyst particles are generally supplied in states having no catalytic activity or exhibiting a decreased catalytic activity such that no flame retardancy can be imparted. Heat treatment is performed to remove crystal water from the particles. Crystal water refers to a water which coordinates or binds to an element in the molecule, a water which fills a vacant site in the crystal lattice, a water which is contained as OH ion and dehydrated as H₂O upon heating, or the like, and these waters are removed by being heated at elevated temperatures. Removing crystal water from the silica-magnesia catalyst particles requires heat treatments at a temperature of 100° C. or higher, preferably at a temperature of 200° C. to 350° C. The temperature at which a resin component having poly(lactic acid) and/or a lactic acid copolymer as the main ingredient is kneaded is at the highest in the order of 260° C., and thus the heat treatment for removing any crystal water needs to be carried out separately before the kneading. In addition, the heat treatment is preferably carried out in an atmosphere under 0.1 atm or less. Therefore, suction evacuation is preferably performed during the heat treatment.

An outer casing according to the present disclosure is obtained by shaping a desired shape from the flame-retarded resin composition by injection molding, extrusion molding, or compression molding. In order that at least a portion of the molded surface is a shiny surface, it is preferable that the outer casing is produced by injection molding or by compression molding, using a mold of which at least a portion of the inner surface has been subjected to mirror finish machining. Injection molding and extrusion molding involve a step of melting the flame-retarded resin composition produced by the above-described method and kneading the molten resin composition by the use of a kneader or the like. Therefore, when these molding methods are employed, the addition of the flame retardance-imparting component to the resin component may be carried out in this kneading step. If the flame retardance-imparting component is added in that manner, then a separate step for adding the flame retardance-imparting component is not required, and thus the outer casing is efficiently obtained.

As mentioned above, the front cabinet 6 of the outer casing 5 in the liquid crystal display device or the like is provided with the speaker grille 6b for releasing sounds emanated from the speaker to the outside. In the outer casing like this, the sound waves from the speaker will cause vibration in the front cabinet 6, due to which an unusual noise, a so-called “chatter noise”, may generate.

The present inventors have made an investigation on how to suppress a chatter noise in the front cabinet 6 which is made by molding the flame-retarded resin composition including the resin component and silica-magnesia catalyst particles, wherein the resin component contains 50% by weight or more of poly(lactic acid) and/or a lactic acid copolymer. From the results, the present inventors have found that the flexural strength of the resin compositions used for the front cabinet 6 affects the generation of a chatter noise.

Specifically, as shown in the Examples section which follows, it turned out that when the flexural strength of the flame-retarded resin composition to be molded was 40 MPa or more, the generation of a chatter noise was able to be suppressed. A more preferable flexural strength of the flame-retarded resin composition to be molded is 2 GPa or more. The flexural strength of the resin composition is measured according to ISO 178 (JIS K 7171) using a specimen with a length, width, and thickness of 80 mm×10 mm×4 mm which are molded by injection molding of the resin composition using a cylinder temperature of 185° C., a mold temperature of 100° C., and a cooling period of 60 seconds.

The flexural strength of the flame-retarded resin composition is also related to the degree of crystallinity of poly(lactic acids) and/or lactic acid copolymers. The higher the degree of crystallinity of poly(lactic acid) and/or a lactic acid copolymer, the higher the flexural strength of the resin composition tends to become. The degree of crystallinity of a molded article for making up the outer casing according to the present disclosure is preferably 35% or more. Here, the degree of crystallinity of the molded article is determined by calculation from its heat of fusion which is measured using a DSC (differential scanning colorimeter). Specifically, the degree of crystallinity is calculated by determining the ratio of a heat of fusion of an actual molded article which is measured using a DSC (an enthalpy of fusion) to a heat of fusion when it is assumed that the degree of crystallinity is 100% (a theoretical value). For poly(lactic acid), the heat of fusion when it is assumed that the degree of crystallinity is 100% (a theoretical value; an enthalpy of fusion for an infinite lamella size which was determined by Fisher et al.) is 93 J/g. The rate at which the temperature of a DSC is increased in determining the heat of fusion is set to be 20° C. per minute.

The resin composition for making up a molded article which meets the above-described degree of crystallinity has a high flexural strength also at elevated temperatures (above its glass transition temperature), and thus exhibits satisfactory moldability. If the resin composition has a low flexural strength at elevated temperatures, then the resin composition will be soft at these temperatures, making it difficult for the resulting molded article to be removed from the mold. Therefore, it is preferable to determine the composition of the flame-retarded resin composition, so as to meet the above-described degree of crystallinity. The degree of crystallinity is also affected by conditions under which the resin composition is molded, and thus it is preferable that molding conditions for the outer casing are selected so as to increase the degree of crystallinity.

The amount of addition of an impact absorber (also referred to as an impact modifier) which is employed to improve the impact resistance of the resin composition is related to the degree of crystallinity and the flexural strength. Increased amounts of the impact absorber will result in the decrease in the degree of crystallinity. In other words, when a comparison is made of resin compositions having the same degree of crystallinity, the higher the amount of the impact absorber, the lower the flexural strength. Therefore, when the impact absorber is added, the amount at which the impact absorber is added is selected as appropriate, so as to obtain a desired impact resistance and flexural strength. In general, the amount of the impact absorber to be added is preferably 5% by weight or less of the resin composition. The impact absorber is preferably added such that the Charpy impact value of the resin composition is 6 kJ/m² or more. A more preferable Charpy impact value of the resin composition is from 6 kJ/m² to 20 kJ/m². Charpy impact values of the resin composition is measured according to ISO 179 (JIS K 7111) using a specimen with a length, width, and thickness of 80 mm×10 mm×4 mm and with a notch of 45° and 2 mm depth, which is molded by injection molding of the resin composition using a cylinder temperature of 185° C., a mold temperature of 100° C., and a cooling period of 60 seconds.

Setting the flexural strength of the resin composition to be a particular value or more as described above will make it possible to suppress the generation of a “chatter noise” in a product into which the molded outer casing has been incorporated, for example, a liquid crystal display. An outer casing is usually molded so as to have a thinner thickness, in order to reduce the amount of the resin composition used. Hence, an outer casing is usually provided with ribs on the other side (i.e. the reverse side) of the outer surface (design surface), even though the resin composition has a high flexural strength. Specifically, the front cabinet 6 of a liquid crystal display device or the like is provided, as shown in FIG. 5, with a plurality of ribs (6d) on the reverse side which is the other side of a design surface 6c that is visible from outside, and in such a manner that they are at right angles to the design surface 6c, in order to ensure its mechanical strength.

The resin composition including PLA and/or a lactic acid copolymer as the main ingredient of its resin component has a high volume shrinkage during molding. As a result, when such a resin composition is subjected to molding into an outer casing 6 having ribs 6d as shown in FIG. 5, shrinkage becomes prominent particularly around each of the ribs 6d, and is prone to causing a dimple, referred to as a “sink”, on the design surface 6c at the site corresponding to each of the ribs 6d. These dimples will reduce or destroy the commercial value of the outer casing.

The present inventors have made an investigation on how to suppress the occurrence of sinks in a molded article which is made of a resin composition including PLA and/or a lactic acid copolymer as the main ingredient of its resin component. From the results, the present inventors have found that there is a relationship between the occurrence of a sink and the thickness of a rib 6 at its base. Specifically, it has been found by the present inventors that it is preferable that the thickness of a rib at its base is 1.25 mm or less. Such ribs can suppress the occurrence of sinks affecting the design surface (molded surface) and will not impair the external beauty. Here, the base of a rib refers to a portion at which the rib stands on the reverse side of the design surface. The thickness of a rib corresponds to the thickness of a rib which is formed into a thin plate.

In the outer casing according to the present disclosure which is configured in this way, a molded surface is shiny, such that its 20 degree specular glossiness (Gₛ(20°)) which is measured according to JIS Z 8741, is 60 or more, and exerts superior effects of a design. The outer casing according to the present disclosure has a glossy molded surface by using a resin composition which has a flexural strength of a given value or more, and preferably does not include a filler. Such an outer casing can be incorporated into a product, wherein a molded surface is as a design surface as it is, without being subjected to a step of painting and polishing, and thereby effects of the design are exerted.

The specular glossiness of a surface (Gₛ(θ), wherein θ is an angle of incidence), is measured according to JIS Z 8741. Specifically, determinations are made of a specular light flux φs from a given surface of a specimen at a specified angle of incidence θ (an angle between the optical axis of a light detector system and the normal line of the given surface of the specimen) and of a specular light flux φos from a standard surface at the specified angle of incidence θ, and calculation is performed according to the equation which follows, in which Gos(θ) is a glossiness of the standard surface used. The standard surface is a surface of a glass with a refractive index of 1.567.

$${G}_{s} ( θ ) = \frac{{ϕ}_{s}}{{ϕ}_{ox}} \cdot {G}_{os} ( θ ) \qquad [ Equation 1 ]$$

An outer casing for an electric device according to the present disclosure is used, in particular, as an outer casing not only for the above-described liquid crystal display device, but also for other display devices (plasma display devices, organic EL display devices and the like), for computers, mobile phones, audio products (for example, radios, cassette decks, CD players, MD players), microphones, keyboards, and potable audio players, and for electric parts. Electric devices are not limited to ones for family use. Electric devices include ones for business use, such as industrial use and medical use.

### EXAMPLES

### Experiment 1

Several flame-retarded resin compositions were prepared, each composition including a resin component containing 50% by weight or more of poly(lactic acid) and/or a lactic acid copolymer, and silica-magnesia catalyst particles as a flame retardance-imparting component which imparts flame retardancy. The compositions were different in flexural strength from each other. Each of these resin compositions was a resin composition including 70% by weight poly(lactic acid), 8% by weight silica-magnesia catalyst particles (with an average particle size of 5 μm), and 3% by weight a styrenic elastomer as an impact absorber, and additionally a total of 19% by weight other ingredients, such as a crystal nucleating agent, a hydrolysis inhibitor, a filler, a compatibilizer, a plasticizing agent, a mold release agent, and the like. The flexural strengths of these resin compositions were varied by changing the type of poly(lactic acid). The flexural strengths and Charpy impact values of these resin compositions are as shown in Table 1. Each of these resin compositions was used for injection molding into a front cabinet 6 shown in FIG. 1. Sounds with frequencies ranging from 20 Hz to 20000 Hz were generated by a speaker placed in the front cabinet 6, and the presence or absence of the generation of a chatter noise was determined by a method of human auditory evaluation (sensory evaluation). Further, the 20 degree specular glossiness was evaluated on a design surface of the outer casing of each of Examples and Comparative Examples. The results are shown in Table 1.

TABLE 1

| | Flexural | Charpy | | | 20 Degree |
|---|---|---|---|---|---|
| | strength | impact | Chatter | | specular |
| | (MPa) | (kJ/m²) | noise | Moldability | glossiness |
| Example 1 | 65 | 25 | Not | + | 70 |
| | | | detected | | |
| Example 2 | 40 | 15 | Not | + | 65 |
| | | | detected | | |
| Example 3 | 85 | 6 | Not | + | 80 |
| | | | detected | | |
| Comp. Ex. 1 | 35 | 20 | Detected | − | 50 |
| Comp. Ex. 2 | 30 | 25 | Detected | − | 45 |

As shown in Table 1, Examples 1 to 3, which are in accordance with the present disclosure, are examples in which the cabinet was made up of the flame-retarded resin composition having a flexural strength of 40 MPa or more. These examples allowed the generation of a chatter noise to be suppressed.

Further, it proved, from the results of the experiments performed by the present inventors, that it was desirable that the flexural modulus of flame-retarded resin composition was 2 GPa or more.

Therefore, it is possible that the generation of a chatter noise, for example, due to vibrations resulting from sounds from a speaker, is suppressed in an outer casing for an electric device that is formed by molding of a flame-retarded resin composition which includes a resin component containing poly(lactic acid) and/or a lactic acid copolymer as the main ingredient, and silica-magnesia catalyst particles as a flame retardance-imparting component, and has a flexural strength of 40 MPa or more.

### Experiment 2

An investigation was made of the relationship between the occurrence of a sink and the thickness of a rib 6d at its base. An outer casing 6 as shown in FIG. 1 which was provided with ribs 6d on the reverse side of a design surface 6c was made using the flame-retarded resin composition used in Example 1 described above. Examples and Comparative Examples were each made by injection molding, such that the thicknesses of the respective ribs 6d at their base were different from each other as shown in Table 2. In these Examples and Comparative Examples, an examination was made of whether or not sinks affecting the design surface 6c had been caused. The presence or absence of sinks is shown in Table 2.

TABLE 2

| | Thickness at rib base (mm) | Occurrence of sinks |
|---|---|---|
| Example 4 | 1.20 | Not observed |
| Example 5 | 1.25 | Not observed |
| Comp. Ex. 3 | 1.30 | Observed |
| Comp. Ex. 4 | 1.40 | Observed |

As will be apparent from this Table 2, the occurrence of sinks affecting a glossy design surface 6c was able to be suppressed by setting the thickness of the respective ribs 6d at their base to be 1.25 mm or less, wherein the ribs 6d were provided on the reverse side of and at right angles to the design surface 6c. The occurrence of no sinks results in the effect that the external beauty of the outer casing is not impaired.

An outer casing for an electric device according to the present disclosure is produced by employing an environmental resin which has a small burden to the environment, possesses flame retardancy, tends not to cause the generation of a chatter noise and of sinks, and has a glossy surface like a mirror surface, and thus is useful as an outer casing for a liquid crystal display and the like.

### DESCRIPTION OF REFERENCE NUMBERS

1: Display device body
5: Outer casing
6: Front cabinet
6c: Design surface
6d: Rib

What is claimed is:

1. An outer casing for an electric device, comprising a molded article which is made up of a flame-retarded resin composition, the resin composition comprising a resin component comprising 50% by weight or more of poly(lactic acid) and/or a lactic acid copolymer, and silica-magnesia catalyst particles as a flame retardance-imparting component which imparts flame retardancy,
wherein the resin composition has a flexural strength of 40 MPa or more, and
the molded article has a glossy surface having a 20 degree specular glossiness (Gₛ(20)) of 60 or more, measured according to JIS Z 8741.

2. The outer casing for an electric device according to claim 1, wherein the resin composition has a flexural modulus of 2 GPa or more.

3. The outer casing for an electric device according to claim 1, wherein the outer casing comprises ribs which are placed on the reverse side of and at right angles to the glossy surface and the thickness of the ribs at their base is 1.25 mm or less.

4. The outer casing for an electric device according to claim 1, wherein the molded article has a degree of crystallinity of 35% or more.

5. The outer casing for an electric device according to claim 1, wherein the molded article does not include a filler.
